(19) United States
(12) Patent Application Publication
(10) Pub. No.: US 2006/0196580 A1
(43) Pub. Date: Sep. 7, 2006

(54) Method of making a Nb3Sn-based superconducting wire

(75) Inventors: Genzo Iwaki, Mito (JP); Morio Kimura, Kasumigaura (JP); Kohei Tagawa, Tsuchiura (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: HITACHI CABLE, LTD., Tokyo (JP)

(21) Appl. No.: 11/362,511

(22) Filed: Feb. 27, 2006

(30) Foreign Application Priority Data
Feb. 28, 2005 (JP) 2005-54638

(51) Int. Cl. H01L 39/24

(52) U.S. Cl. 148/98

(57) ABSTRACT

A method of making a Nb₃Sn-based superconducting wire has: providing a drawn wire having a sub-element wire that a plurality of filaments having niobium (Nb) or an niobium alloy are disposed in a bronze material having a copper (Cu)-tin (Sn)-based alloy material; and a heat treatment step of heating the drawn wire to generate a Nb₃Sn-based superconducting phase in the sub-element wire. The heat treatment step has heating the drawn wire at a rate of temperature rise of 0.5 to 10° C./hour and with a temperature width of 30 to 200° C.

The present application is based on Japanese patent application No. 2005-054638 filed Feb. 28, 2005, the entire contents of which are incorporated herein by reference.

### BACKGROUND OF THE INVENTION

1. Field of the Invention

This invention relates to a method of making a Nb₃Sn-based superconducting wire and, particularly, to a method of making a Nb₃Sn-based superconducting wire with an excellent superconductive property at a reduced manufacturing cost.

2. Description of the Related Art

Superconducting magnets that are used to generate a high magnetic field have been applied to NMR (nuclear magnetic resonance) equipments, nuclear fusion equipments etc. A representative superconducting wire for the superconducting magnet is a Nb₃Sn-based superconducting wire.

Known as a method of making the Nb₃Sn-based superconducting wire are the internal diffusion process, tube process, in-situ process, powder process, bronze process etc. Especially, the bronze process is most widely used.

In making the Nb₃Sn-based superconducting wire by the bronze process, diffusion heat treatment is needed to generate a Nb₃Sn-based superconducting phase. In general, conditions of the heat treatment are 650 to 700° C. for 90 to 200 h (e.g., JP-A-2004-35940).

In order to increase the critical current density of the Nb₃Sn-based superconducting wire, a method is disclosed that uses a temperature rise rate of 15° C./h and 25° C./h and a heat treatment of 570° C./185 h+625° C./175 h (H. Sakamoto et al.: “Very High Critical Current Density of Bronze-Processed (Nb, Ti)₃Sn Superconducting Wire”, IEEE Trans. Appl. Supercond. 10 (2000) pp. 971-974).

However, the method of JP-A-2004-35940 has problems as described below. Although the heat treatment time for generating the Nb₃Sn-based superconducting phase can be shortened by the method, enhancement of superconducting property (critical current density) must be impeded due to limitations of used materials (e.g., a limitation in Sn concentration of the bronze). Further, the process must be highly complicated in obtaining the excellent superconductive property.

Although the method of H. Sakamoto et al. can solve the above problems, the heat treatment time for generating the Nb₃Sn-based superconducting phase must be significantly longer. Thus, the manufacturing cost will be increased.

### SUMMARY OF THE INVENTION

It is an object of the invention to provide a method of making a Nb₃Sn-based superconducting wire that can offer a Nb₃Sn-based superconducting wire with an excellent superconductive property (especially, enhanced critical current density characteristics) while reducing the heat treatment time for generating the Nb₃Sn-based superconducting phase.

(1) According to one aspect of the invention, a method of making a Nb₃Sn-based superconducting wire comprises: providing a drawn wire comprising a sub-element wire that a plurality of filaments comprising niobium (Nb) or an niobium alloy are disposed in a bronze material comprising a copper (Cu)-tin (Sn)-based alloy material; and

a heat treatment step of heating the drawn wire to generate a Nb₃Sn-based superconducting phase in the sub-element wire,

wherein the heat treatment step comprises heating the drawn wire at a rate of temperature rise of 0.5 to 10° C./hour and with a temperature width of 30 to 200° C.

In the above invention (1), the following modifications and changes can be made.

(i) The Nb₃Sn-based superconducting wire is made by using the bronze process.

(ii) The heat treatment step comprises heating the drawn wire at a rate of temperature rise of 0.5 to 10° C./hour and with a temperature width of 30 to 200° C. for 10 to 140 hours.

(iii) The heat treatment step comprises a heat treatment start temperature or a minimum temperature in the heat treatment step to be in the range of 500 to 610° C., and a heat treatment end temperature or a maximum temperature in the heat treatment step to be in the range of 620 to 720° C.

(iv) The heat treatment step defines an area bounded by a vertical-axis temperature (K, absolute temperature) and a horizontal-axis time (h), the area being 10,000(K·h) or more and 100,000 (K·h) or less.

(2) According to another aspect of the invention, a method of making a Nb₃Sn-based superconducting wire comprises:

providing a drawn wire comprising a sub-element wire that a plurality of filaments comprising niobium (Nb) or an niobium alloy are disposed in a bronze material comprising a copper (Cu)-tin (Sn)-based alloy material; and

a heat treatment step of heating the drawn wire to generate a Nb₃Sn-based superconducting phase in the sub-element wire,

wherein the heat treatment step comprises heating the drawn wire at a rate of temperature rise of 0.5 to 10° C./hour, and

the heat treatment step defines an area bounded by a vertical-axis temperature (K, absolute temperature) and a horizontal-axis time (h), the area being 10,000(K·h) or more and 100,000 (K·h) or less.

### ADVANTAGES OF THE INVENTION

A method of making a Nb₃Sn-based superconducting wire according to the invention can offer a Nb₃Sn-based superconducting wire with an excellent superconductive property (especially, enhanced critical current density characteristics) while reducing the heat treatment time for generating the Nb₃Sn-based superconducting phase.

### BRIEF DESCRIPTION OF THE DRAWINGS

The preferred embodiments according to the invention will be explained below referring to the drawings, wherein:

FIG. 1 is a flow chart showing a method of making a Nb₃Sn-based superconducting wire in a preferred embodiment according to the invention;

FIG. 2 is a cross sectional view showing the Nb₃Sn-based superconducting wire of the embodiment;

FIG. 3 is a flow chart showing a heat treatment step for generating a Nb₃Sn-based superconducting phase in the embodiment;

FIGS. 4A to 4C are diagrams showing an example of the heat treatment step for generating the Nb₃Sn-based superconducting phase in the embodiment; and

FIG. 5 is a diagram showing an example of an area bounded by a vertical-axis temperature (K, absolute temperature) and a horizontal-axis time (h) in heat treatment step A.

### DETAILED DESCRIPTION OF THE PREFEPRED EMBODIMENTS

Method of Making a Nb₃Sn-Based Superconducting Wire

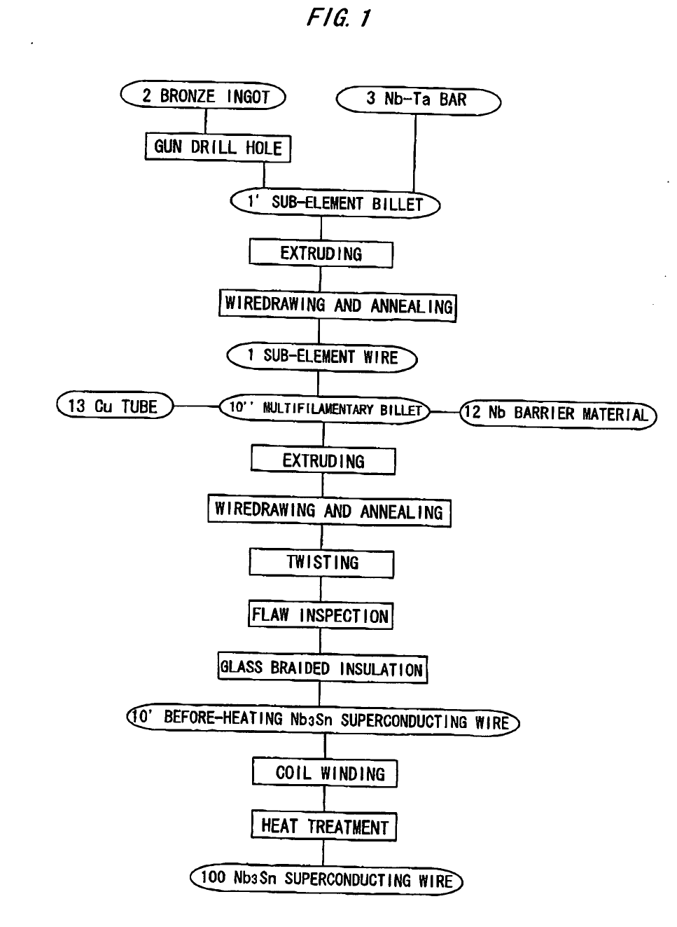

FIG. 1 is a flow chart showing a method of making a Nb₃Sn-based superconducting wire in a preferred embodiment according to the invention. The method of making the same will be explained below referring to FIG. 1.

The method as shown in FIG. 1 is a method of making the Nb₃Sn-based superconducting wire by using the bronze process. Thus, steps except the heat treatment steps for generating the Nb₃Sn-based superconducting phase can be the same as the conventional bronze process. Hereinafter, even when simply described Nb₃Sn, it means all Nb₃Sn-based superconducting intermetallic compounds such as (Nb, Ti)₃Sn, (Nb, Ti, Ta)₃Sn etc.

For example, there are provided a bronze ingot 2 (a Cu—Sn-based matrix alloy, e.g., Cu-14Sn-0.3Ti) with 19 holes formed by gun drilling, and a niobium or niobium alloy bar 3 (e.g., Nb-1.0Ta). Then, a sub-element billet 1′ is formed by inserting (or embedding) the niobium or niobium alloy bar 3 into the holes of the bronze ingot 2. Then, a sub-element wire 1 is formed by extruding, and drawing-annealing. The sub-element wire 1 may be circular or hexagonal in cross section.

A wire group of plural sub-element wires 1 thus formed is inserted into a diffusion barrier 12 of niobium etc. A multifilamentary billet 10″ is formed by surrounding it with a stabilizing copper 13. The multifilamentary billet 10″ is then subjected to extruding, wiredrawing-annealing, twisting and flaw inspection. A before-heating Nb₃Sn-based superconducting wire 10′ is obtained by covering it with an insulation layer of glass fiber or ceramic fiber.

In fabricating a superconducting magnet by using the Nb₃Sn-based superconducting wire, so-called Wind & React process is used generally. For example, after the obtained before-heating Nb₃Sn-based superconducting wire 10′ is coiled to a magnet etc., it is subjected to a heat treatment step to generate a Nb₃Sn-based superconducting phase. Thus, a Nb₃Sn-based superconducting coil 100 (i.e., a superconducting magnet using a Nb₃Sn-based superconducting wire 10) can be obtained.

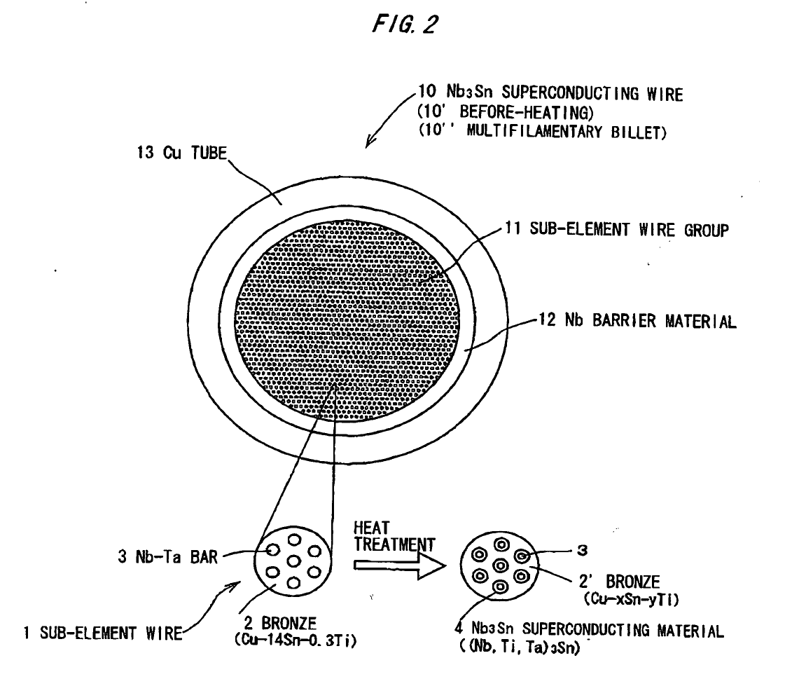

FIG. 2 is a cross sectional view showing the Nb₃Sn-based superconducting wire of the embodiment.

The multifilamentary billet 10″ comprises a sub-element wire group 11 that is formed bundling the plural sub-element wires 1 composed of the bronze 2 (Cu-14Sn-0.3Ti) and the Nb filament 3 (Nb-1.0Ta), the Nb barrier material 12 that is formed around the wire group, and the Cu tube 13 that is formed around the Nb barrier material 12.

The Nb barrier material 12 functions as a diffusion barrier layer. The Nb barrier layer 12 is disposed because, when conducting the heat treatment to generate the Nb₃Sn-based superconducting phase, Sn contained in the bronze 2 diffuses outward and contaminates the Cu to function as a stabilizing material whereby the resistivity of the stabilizing material may increase. Thus, the Nb barrier material 12 functions to prevent the diffusion of Sn (i.e., increase in resistivity of Cu). Alternatively, Ta etc. can be used instead of the Nb.

The Cu tube 13 functions as a stabilizing material to stabilize the entire Nb₃Sn-based superconducting wire thermally and electromagnetically. It is generally made of oxygen-free copper. It can be made of aluminum or an aluminum alloy. Although the Cu tube 13 is as shown in FIG. 2 disposed on the periphery of the Nb barrier material 12, it maybe disposed at the central portion of the wire or dispersed in the wire.

By conducting the heat treatment to the before-heating Nb₃Sn-based superconducting wire, Sn or Sn and Ti contained in the bronze 2 (Cu-14Sn-0.3Ti) is diffused toward the Nb filament 3 (Nb-1.0Ta) to react with Nb. Thereby, as shown in FIG. 2, Nb₃Sn-based superconducting phase 4 (e.g., (Nb, Ti, Ta)₃Sn) is produced from the vicinity of the interface of the Nb filament 3 (i.e., the vicinity of the boundary between the bronze 2 and the Nb-2.0Ta) to the inside. Along with this, the bronze 2 (Cu-14Sn-0.3Ti) is changed into a bronze 2′ (Cu-xSn-yTi) in which the content of Sn or Sn and Ti decreases.

Heat Treatment for Generating the Nb₃Sn-Based Superconducting Phase

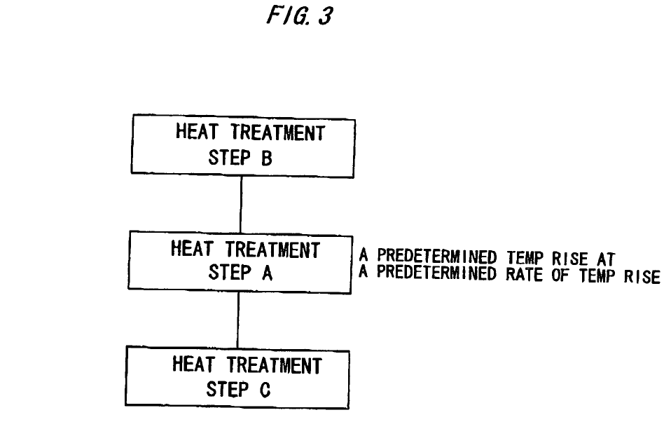

FIG. 3 is a flow chart showing a heat treatment step for generating a Nb3Sn-based superconducting phase in the embodiment.

The heat treatment step comprises a heat treatment step B, a heat treatment A and a heat treatment step C.

The heat treatment for generating the Nb₃Sn-based superconducting phase is characterized by that it is conducted in vacuum or in inert gas such as argon gas, and it comprises the heat treatment step A to heat in a temperature width of 30 to 200° C. at a temperature rise rate of 0.5 to 10° C./h. Herein, “to heat in a temperature width of 30 to 200° C.” means that a difference between the minimum temperature and maximum temperature during the heat treatment step A is in the range of 30 to 200° C. In order to produce an excellent Nb₃Sn-based superconducting phase, it is heated preferably in a temperature width of 70 to 150° C. at a temperature rise rate of 0.6 to 9° C./h, more preferably in a temperature width of 90 to 140° C. at a temperature rise rate of 0.8 to 8° C./h, most preferably in a temperature width of 110 to 130° C. at a temperature rise rate of 1 to 6° C./h.

The heat treatment time of the heat treatment step A is preferably 140 hrs or less, more preferably 100 hrs or less, further preferably 75 hrs or less, most preferably 50 hrs or less. The heat treatment time is preferably 10 hrs or more, more preferably 15 hrs or more, further preferably 20 hrs or more, most preferably 25 hrs or more.

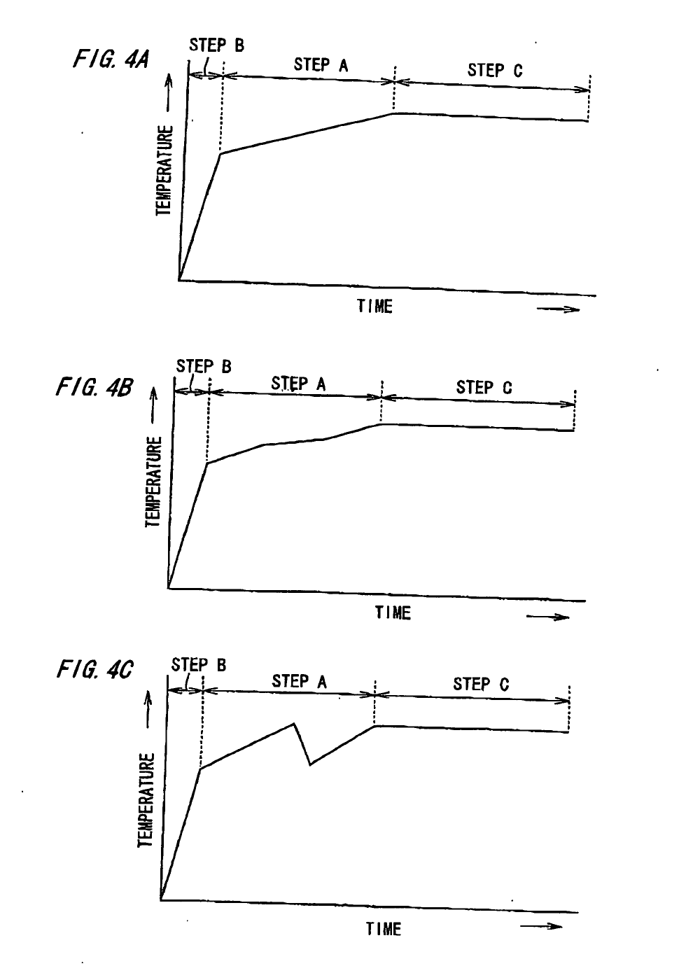

FIGS. 4A to 4C are diagrams showing an example of the heat treatment step for generating the Nb₃Sn-based superconducting phase in the embodiment.

The heat treatment step A may be conducted at a constant temperature rise rate (as shown in FIG. 4A) within the abovementioned temperature rise rate, 0.5 to 10° C./h, or at a variable temperature rise rate within the temperature rise rate (as shown in FIG. 4B). Further, it may include midway a step that temperature lowers (as shown in FIG. 4C).

A start temperature (or a minimum temperature) of the heat treatment step A is to be in the range of 500 to 610° C., preferably 530 to 570° C., and an end temperature (or a maximum temperature) thereof is to be in the range of 620 to 720° C., preferably 640 to 700° C.

The heat treatment step B is to make a temperature rise from room temperature to the above start temperature as soon as possible, though not limited, e.g., 1 to 10 hrs. Alternatively, the heat treatment step B can be omitted by placing the before-heating Nb₃Sn-based superconducting wire 10 in a furnace previously heated at the start temperature.

The heat treatment step C is to conduct a heat treatment at the above end temperature, though not limited, e.g., 90 to 110 hrs.

By the above heat treatment steps (for generating the Nb₃Sn-based superconducting phase), the Nb₃Sn-based superconducting wire with an excellent superconductive property can be obtained in the shortened time period. Thereby, the manufacturing cost can be reduced.

The invention can be also defined as follows.

Namely, the invention is characterized by that, in the heat treatment step A within the temperature rise rate, an area as bounded by a vertical-axis temperature (K, absolute temperature) and a horizontal-axis time (h) in heat treatment step A is 10,000 (K·h) or more and 100,000 (K·h) or less, preferably 20,000 (K·h) or more and 90,000 (K·h) or less.

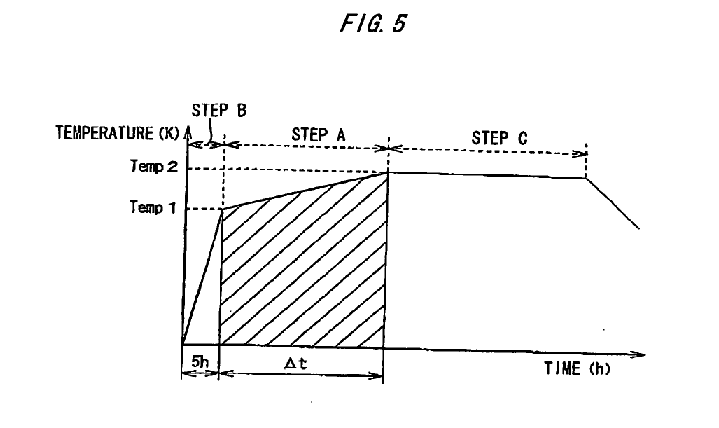

FIG. 5 is a diagram showing an example of an area bounded by a vertical-axis temperature (K, absolute temperature) and a horizontal-axis time (h) in heat treatment step A.

The concerned area is given a part (trapezoid; (Temp 1+Temp 2)×Δt/2) with hatched lines as shown in FIG. 5.

Although the mechanism of generating the Nb₃Sn-based superconducting phase with the excellent superconducting property by the above steps is not perfectly clarified at present, it is assumed that two properties, i.e., the nucleation rate of the Nb₃Sn-based superconducting phase and the growth rate (diffusion reaction rate) thereof relate to the factors of the invention, and the effects of the invention are made by the interaction of the two properties.

The invention will be exemplified by Examples below, but not limited thereby.

### EXAMPLES

Manufacture of Nb₃Sn-Based Superconducting Wires

Nb₃Sn-based superconducting wires (=Example 1 to 5) are manufactured according to the method of making the Nb₃Sn-based superconducting wire in the above embodiment according to the invention.

For comparison, a Nb₃Sn-based superconducting wire (=Comparative example 1) is manufactured by the conventional method of the Nb₃Sn-based superconducting wire.

The Nb₃Sn-based superconducting wires in Examples 1 to 5 and Comparative example 1 are a rectangular wire with a thickness of 1.0 mm, a width of 1.6 mm and a corner radius of 0.3 mm, wherein a superconducting portion (bronze+Nb filament) is incorporated with a volume ratio of 48%. The bronze is of Cu-14.3 wt % Sn-0.3 wt % Ti alloy, and the Nb filament is of Nb-1 wt % Ta alloy. The diameter of the Nb—Ta alloy filament in the rectangular bronze-processed Nb₃Sn-based superconducting wire is 4.4 micrometers. The superconducting portion is isolated from the outer stabilizing copper by the Nb diffusion barrier material with a volume ratio of 5%.

Table 1 shows heat treatment conditions for generating the Nb₃Sn-based superconducting wires of Examples 1 to 5 and Comparative example 1. In the heat treatment conditions, (AAA° C.-BBB° C.)/XXXh means that the temperature increases or decreases at a constant speed from AAA° C. to BBB° C. during XXX time period (hrs), which corresponds to the heat treatment step B or A in the embodiment of the invention. The heat treatment step C following the heat treatment step A is set to be 670° C.×96 h generally used. Comparative example 1 is conducted using the conventional heat treatment steps (=heat treatment steps B and C) not including the heat treatment step A.

Measurement of Critical Current Characteristics

In order to confirm the effects of the invention, the critical current characteristics in Examples 1 to 5 and Comparative example 1 are measured. The critical current is a value measured applying an external magnetic field of 16T with a criterion of 0.1 microvolt/cm. The results are as shown in Table 1.

TABLE 1
<Heat treatment conditions and measurements of critical current>

| | | Critical |
|---|---|---|
| | Heat treatment conditions | current at 16 T |
| Example 1 | (RT-550° C.)/5 h + | 232 A |
| | (550° C.-670° C.)/25 h + | |
| | 670° C. × 96 h then cooling | |
| Example 2 | (RT-550° C.)/5 h + | 240 A |
| | (550° C.-670° C.)/50 h + | |
| | 670° C. × 96 h then cooling | |
| Example 3 | (RT-550° C.)/5 h + | 245 A |
| | (550° C.-670° C.)/100 h + | |
| | 670° C. × 96 h then cooling | |
| Example 4 | (RT-550° C.)/5 h + | 234 A |
| | (550° C.-670° C.)/25 h + | |
| | (670° C.-550° C.)/3 h + | |
| | (550° C.-670° C.)/25 h + | |
| | 670° C. × 96 h then cooling | |
| Example 5 | (RT-550° C.)/5 h + | 243 A |
| | (550° C.-600° C.)/10 h + | |
| | (600° C.-650° C.)/25 h + | |
| | (650° C.-670° C.)/15 h + | |
| | 670° C. × 96 h then cooling | |
| Comparative | (RT-670° C.)/5 h + | 213 A |
| example 1 | 670° C. × 96 h then cooling | |

Note)
RT: room temperature

In Examples 1 to 3, the speed of temperature rise in the range of (550-670° C.) is changed to confirm the effect thereof. As shown in Table 1, there occurs a slight difference in the effect depending on the speed of temperature rise. However, it is confirmed that all of Examples 1 to 3 have a significant enhancement in critical current as compared to comparative example 1.

In Examples 4 to 5, the speed of temperature rise and drop in the range of (550° C.-670° C.) are changed to confirm the effect thereof. As shown in Table 1, there occurs a slight difference in the effect depending on the speed of temperature rise and drop. However, it is also confirmed that all of Examples 4 to 5 have a significant enhancement in critical current as compared to Comparative example 1.

In Examples 1 to 5, the area bounded by the vertical-axis temperature (K, absolute temperature) and the horizontal-axis time (h) in heat treatment step A is as follows.

Example 1: ((550+273)+(670+273))×25/2=22075

Example 2: ((550+273)+(670+273))×50/2=44150

Example 3: ((550+273)+(670+273))×100/2=88300

Example 4: ((550+273)+(670+273))×25/2+((670+273)+(550+273))×3/2+((550+273)+(670+273))×25/2=46799

Example 5: ((550+273)+(600+273))×10/2+((600+273)+(650+273))×25/2+((650+273)+(670+273))×15/2=44925

As a result, it is confirmed that the excellent critical current characteristics can be obtained when the area bounded by the vertical-axis temperature (K, absolute temperature) and the horizontal-axis time (h) in heat treatment step A is in the range of about 22000 to about 89000 (K·h).

Although the above Examples 1 to 5 are rendered to the specific components of bronze and Nb filament, Cu-14.3 wt % Sn-0.3 wt % Ti and Nb-1 wt % Ta, respectively, the excellent critical current characteristics can be obtained in the bronze-processed Nb₃Sn-based superconducting wire with any components of bronze and Nb filament.

Further, the invention can be applied to any heat treatment process for a Nb₃Sn-based superconducting wire other than the bronze-processed Nb₃Sn-based superconducting wire, e.g., for an internal tin processed Nb₃Sn-based superconducting wire that is not subjected to the annealing to soften the components in its manufacturing process.

Although the invention has been described with respect to the specific embodiments for complete and clear disclosure, the appended claims are not to be thus limited but are to be construed as embodying all modifications and alternative constructions that may occur to one skilled in the art which fairly fall within the basic teaching herein set forth.

What is claimed is:

1. A method of making a Nb₃Sn-based superconducting wire, comprising:
providing a drawn wire comprising a sub-element wire that a plurality of filaments comprising niobium (Nb) or an niobium alloy are disposed in a bronze material comprising a copper (Cu)-tin (Sn)-based alloy material; and
a heat treatment step of heating the drawn wire to generate a Nb₃Sn-based superconducting phase in the sub-element wire,
wherein the heat treatment step comprises heating the drawn wire at a rate of temperature rise of 0.5 to 10° C./hour and with a temperature width of 30 to 200° C.

2. The method according to claim 1, wherein:
the Nb₃Sn-based superconducting wire is made by using the bronze process.

3. The method according to claim 1, wherein:
the heat treatment step comprises heating the drawn wire at a rate of temperature rise of 0.5 to 10° C./hour and with a temperature width of 30 to 200° C. for 10 to 140 hours.

4. The method according to claim 1, wherein:
the heat treatment step comprises a heat treatment start temperature or a minimum temperature in the heat treatment step to be in the range of 500 to 610° C., and a heat treatment end temperature or a maximum temperature in the heat treatment step to be in the range of 620 to 720° C.

5. A method of making a Nb₃Sn-based superconducting wire, comprising:
providing a drawn wire comprising a sub-element wire that a plurality of filaments comprising niobium (Nb) or an niobium alloy are disposed in a bronze material comprising a copper (Cu)-tin (Sn)-based alloy material; and
a heat treatment step of heating the drawn wire to generate a Nb₃Sn-based superconducting phase in the sub-element wire,
wherein the heat treatment step comprises heating the drawn wire at a rate of temperature rise of 0.5 to 10° C./hour, and
the heat treatment step defines an area bounded by a vertical-axis temperature (K, absolute temperature) and a horizontal-axis time (h), the area being 10,000(K·h) or more and 100,000 (K·h) or less.
